(19) United States
(12) Patent Application Publication
(10) Pub. No.: US 2012/0112178 A1
(43) Pub. Date: May 10, 2012

(54) OPTOELECTRONIC DEVICES

(75) Inventors: Richard Friend, Cambridgeshire (GB); Wilheim Huck, Cambridgeshire (GB); Guoli Tu, Wuhan (CN); Henning Sirringhaus, Cambridgeshire (GB); Neil Greenham, Cambridgeshire (GB); Martin Heeney, Surrey (GB)

(73) Assignee: CAMBRIDGE ENTERPRISE LIMITED, Cambridge, Cambridgeshire (GB)

(21) Appl. No.: 13/383,159

(22) PCT Filed: Jul. 12, 2010
(86) PCT No.: PCT/GB10/51138

§ 371 Date: Jan. 20, 2012

(30) Foreign Application Priority Data
Jul. 10, 2009 (GB) 0912041.1

(51) Int. Cl. H01L 51/46; H01L 51/48

(52) U.S. Cl. 257/40; 438/82; 257/E51.026

(57) ABSTRACT

An optoelectronic device comprises electon donor D and acceptor A semiconducting species and an intervening co-oligomeric or copolymeric species provided to alter the energy transfer characteristics of excitons to or from the interface between the said electron acceptor and donor species. The intervening species may be of the form Aₘ-Xₙ-Dₒ, where m, n and o are each 0 or a positive integer and at least two of A, X and D are present.

This invention relates to organic semiconductors and, in particular, although not exclusively, to polymeric semiconductors which are usable in optoelectronic, e.g. photo-responsive, devices.

Semiconducting organic materials make remarkably effective substitutes for conventional inorganic semiconductors in a range of optoelectronic devices including light emitting diodes (LEDs), photovoltaic (PV) diodes, field effect transistors (FETs), and lasers. Among the general class of organic semiconductors conjugated polymers exemplify the considerable material advantages than organic semiconductor may have over inorganic semiconductors including chemically tunable optoelectronic properties and low-temperature, solution-based processing suitable for printed electronics. However, their additional functional potential has not been so widely recognized until recently. One functional advantage offered by conjugated polymers is their capacity to employ both electronic and ionic charge carriers in device operation. Whereas solid state inorganic semiconductors are typically impermeable and unstable towards extrinsic ions, ion transport is at the heart of energy conversion and signaling in the soft functional materials found in nature.

The use of organic semiconductors to construct solar cells offers the possibility for the manufacture of very low cost devices and has the potential to provide a new solar energy technology. Organic semiconductors are generally excellent materials for absorbing incident radiation because they are very strongly absorbing.

Organic solar cells may comprise a layer or film of active layer, the donor layer, and a layer or film of acceptor molecules sandwiched between a pair of contacts. The donor layer may comprise conjugated polymer species which possess delocalized n electrons which can be excited by light (usually visible light) from the highest occupied molecular orbital (HOMO) to the molecules lowest unoccupied molecular orbital (LUMO), a π-π* transition. The band gap between the HOMO and LUMO corresponds to the energy of the light which can be absorbed.

However, the excited state produced by photon absorption does not generally produce a free electron and an associated free positive charge (generally termed as a ‘hole’), but produces instead an electrostatically bound neutral excited states (generally termed as an ‘exciton’). The approach that has been followed within the field is to make use of the heterojunction that can be formed between organic semiconductors with different electron affinities and ionisation potentials. A schematic diagram of this process is demonstrated in FIG. 1.

In FIG. 1, there is shown a single heterostructure device 100. The operation of this structure is such that excitons formed by photon absorption in the bulk donor material 101, step (i), migrate principally through Förster transfer to the nearby heterojunction formed with material 103 (noting that this is usually formed as an appropriate nanoscale structure to maximize the interfacial contact between the two materials), and rapidly undergo electron transfer as shown in step (ii) to the acceptor material 103. The device can alternatively operate by optical absorption in the electron acceptor 103, followed by exciton migration to the donor 101 and electron transfer from donor to acceptor. The simplest energetic criterion that this can operate is that the band edge offsets are both larger than the on-site Coulomb binding of the intramolecular exciton (estimated to be typically of order 0.5 eV).¹

This however ignores the very important role of inter-molecular (or for the case of polymers, inter-chain) Coulomb interactions, and the current inventors have previously demonstrated that the charge transfer state first formed at step (ii) can still be strongly coulombically bound, since electron and hole are still only about 0.4 nm apart and their Coulomb interaction is weakly screened (dielectric constants for organic semiconductors are typically around 3).

Indeed, for several systems this bound Charge Transfer Exciton (CT exciton) is weakly emissive, showing long-lived and red-shifted emission^{2,3}. The long-range separation of charges illustrated at step (iii) is therefore difficult to achieve, requiring an internal DC field that appears in the PV operational performance as a reduced ‘fill factor’ for the solar cell.

A current state-of-the-art device is achieved utilising poly(3-hexylthiophene) (P3HT) as hole acceptor and Phenyl C61 Butyric Acid Methyl Ester (PCBM), a soluble derivative of C₆₀, as electron acceptor. In this system quantum efficiencies above 80% are achieved, but the open circuit voltage is low due to the large (Ca 1 eV) LUMO energy offset. This, together with poor infrared absorption, reduces energy conversion efficiency to near 5%. It seems that this system works because the carrier mobility is high for one of the carriers (electrons) and the excess kinetic energy that results from the large offset in LUMO energy allow a good fraction of the charges to escape one another's Coulomb field^{4,5}. A hidden ‘benefit’ that arises through the large LUMO offset is that any spin triplet exciton that might have formed by intersystem crossing of the CT state will itself be unstable against the CT state.

Recent work by the current inventors on polymer-polymer solar cells has identified the recombination of interfacial charge pairs as a major bottleneck in device efficiency^{6,7}. Such interfacial charge pairs become trapped because the rate of diffusion away from the interface is insufficient to overcome their mutual Coulombic attraction.

It is a non-exclusive object of the invention to improve the efficiency of optoelectronic devices, e.g. optoelectronic devices comprising organic, say conjugated polymeric, species.

Accordingly, a first aspect of the invention provides an optoelectronic device having donor and acceptor species and an intervening species provided to alter the energy transfer characteristics between the acceptor and donor species.

In a second aspect of the invention there is provided an optoelectronic device comprising a conjugated polymeric donor layer of material D, a polymeric conjugated acceptor material A and a further species Aₘ-Xₙ-Dₒ, where m, n and o are each 0 or a positive integer and wherein at least two of A, X and D are present in the further species.

Accordingly, a further aspect of the invention provides an optoelectronic device having donor and acceptor species and an intervening interfacial co-polymeric or co-oligomeric species provided to alter the energy transfer characteristics between the acceptor and donor species.

A and D may represent polymer repeat units for the acceptor and donor polymers respectively.

The further species may be an oligomer.

A further aspect of the invention provides a method of forming an optoelectronic device comprising blending a donor material D, an acceptor material A and an oligomer Aₘ-Xₙ-Dₒ, where m, n and o are each 0 or a positive integer and where at least two of A, X and D are present.

A yet further aspect of the invention provised an optoelectronic device having electron donor D and acceptor A semiconducting species and an intervening co-oligomeric or coploymeric species provided to alter the charge transfer characteristics of electrons and/or holes to or from the interface between the said electron acceptor A and donor D species.

The intervening species may be or comprise species able to introduce spin orbit coupling.

It is to be understood that throughout the specification, each of A and D of the intervening, further or oligomeric species may be the same or different as the acceptor or donor species of the bulk regions respectively. Whilst when using tri-block species it may be preferred for reasons of practicality (e.g. miscibility) to use identical species in one or other of A and D of the intervening further or oligomeric species, other species may be chosen for the purpose of altering (e.g. tuning) the energy level characteristics. Moreover, for reasons set out below, when using di-block species it may be preferred to use similar, but not identical species to those used in one or other of the bulk donor and/or acceptor phases.

In order that the invention may be more fully understood, it will now be described, by way of example only, with reference to the accompanying drawings, in which:

FIG. 1 is a schematic diagram of a prior art single layer heterojunction in a PV device;

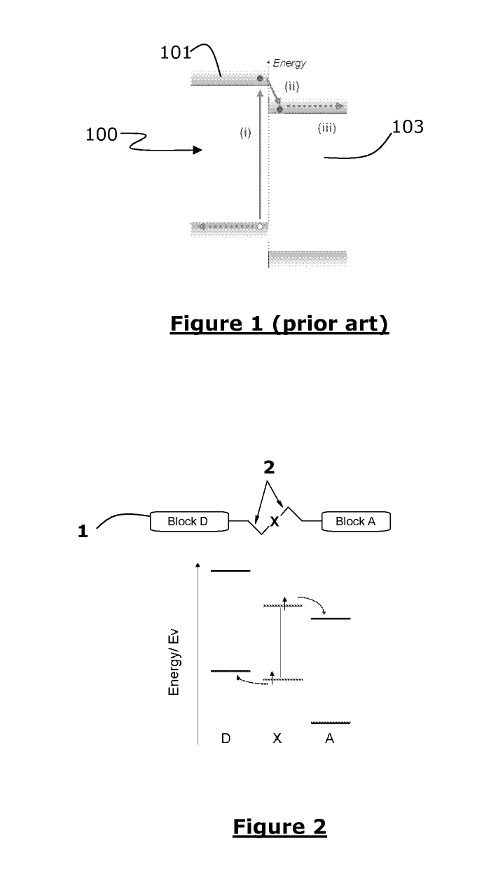

FIG. 2 is a schematic diagram of a functional tri-block that can act as a “surfactant” for polymers A and D according to the invention and a schematic representation of a heterojunction according to the invention;

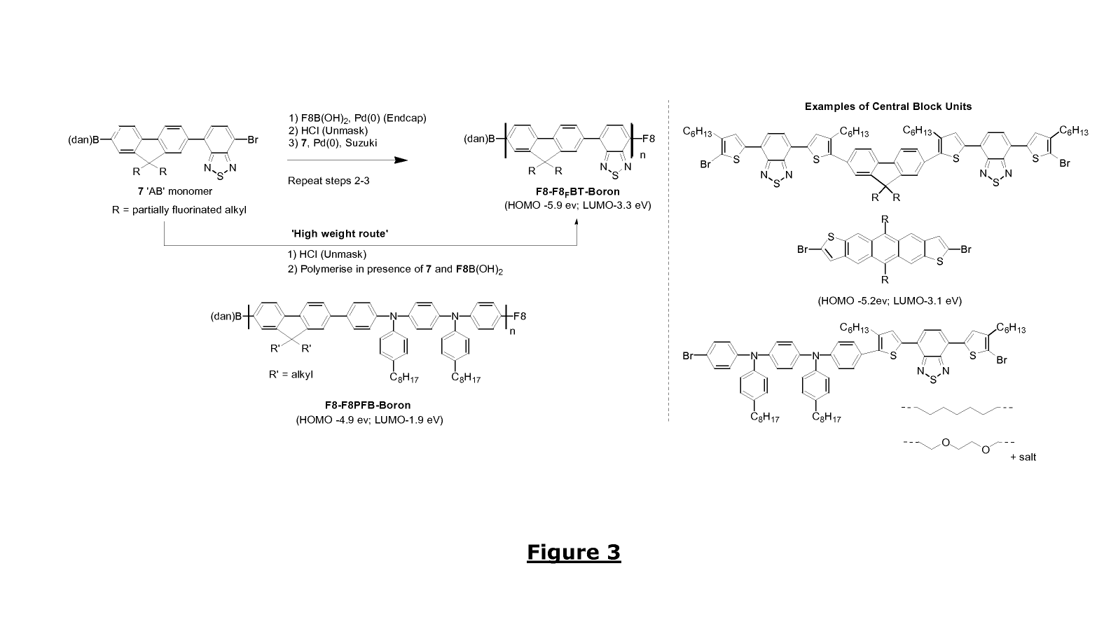

FIG. 3 is a synthetic scheme for the formation of an example triblock

polymer for use with the invention;

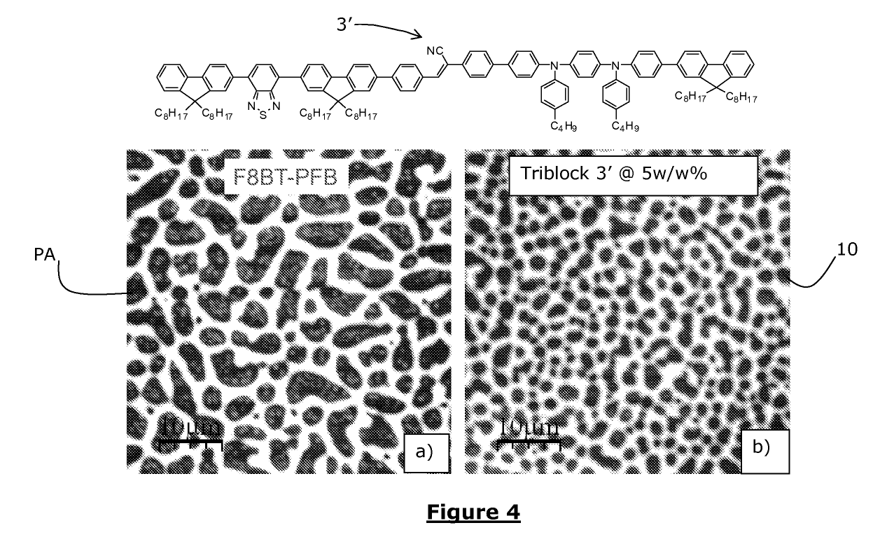

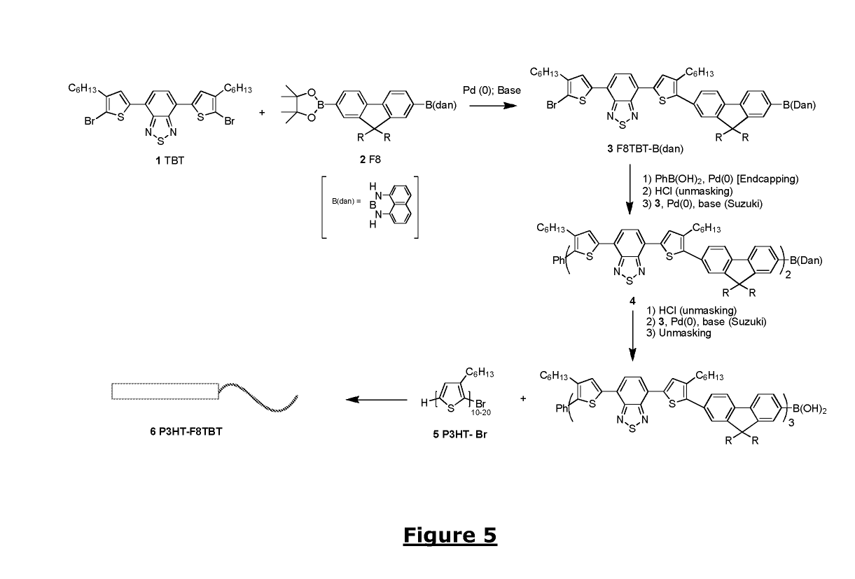

FIG. 4 shows atomic force microscopy images of a) a conventional blend of two polymers and b) a similar blend which comprises 5 w/w % of a tri block species in accordance with the invention;

FIG. 5 is a synthetic scheme for the formation of di-block oligomers for use with the invention;

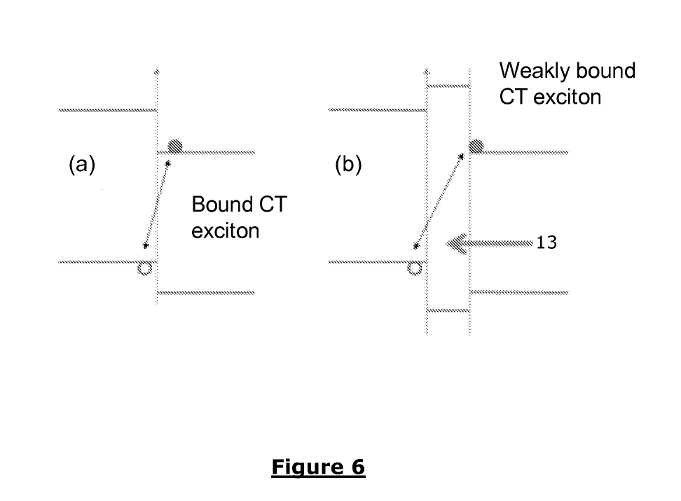

FIG. 6 shows a) a standard heterojunction for an LED, and b) an insulating layer between the hole and electron transport layers according to an aspect of the invention;

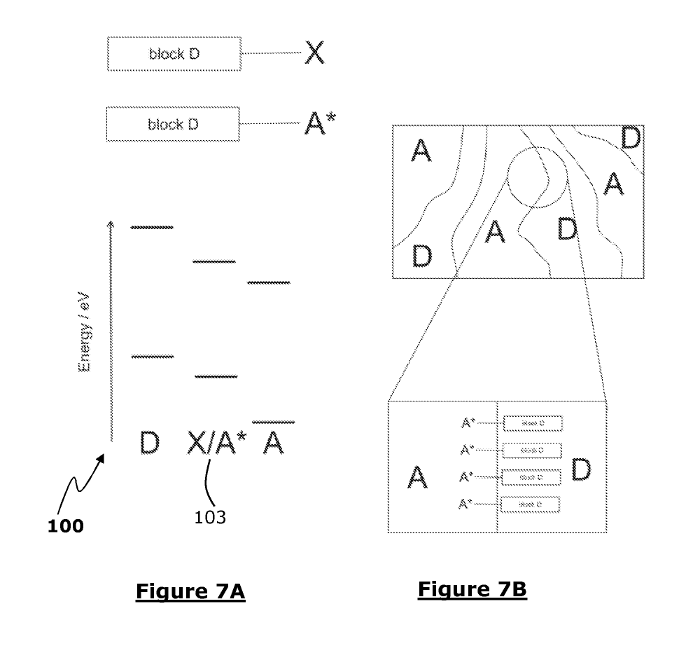

FIG. 7A shows a schematic representation of a further heterojunction according to the invention; and

FIG. 7B is a schematic representation of a blend according to the invention.

As was mentioned in relation to FIG. 1, there is a significant issue which can impair performance at heterojunctions in prior art photovoltaic devices. In order to minimize any such problems, and as shown in FIG. 2, we describe a material in which there is introduced a an additional material X directly at the interface between donor D and acceptor A polymers, thereby providing a tri-block copolymer 1 of general form D-X-A. FIG. 2 shows the material X to have a lower optical band gap than either of the two polymers A and D, with energy levels arranged so that electrons present on X would transfer to A and holes present on X to D. Spacer groups 2 may be present between the donor D and Acceptor A materials.

Material X may be selected more generally, and may comprise an insulator material (including non-conjugated materials) or optional insulating spacer groups may be present between the donor D and acceptor A materials and the material X.

The presence of the low bandgap material X attracts excitons to the interface and improves the efficiency of charge generation. Whilst not wishing to be bound by any theory, this is expected generally to occur via Forster exciton transfer when the emission spectra of either or both of the donor and acceptor materials to either side overlap with the absorption spectrum of the low bandgap material. The structural disorder at prior art polymer-polymer interfaces leads in general to increases in energy levels near the interfaces, thereby hindering migration of excitons by Förster energy transfer towards the interface where charge separation will occur. By placing a lower bandgap material X at the interface, energy transfer from the excited state of the bulk phase to the interfacial low bandgap material X occurs. When the energy levels have been arranged correctly as in FIG. 2 or otherwise, an exciton present on material X will rapidly dissociate, transferring the electron to A and hole to D. The mutual Coulombic attraction of the interfacial charges has been reduced with respect to electron and hole present at adjacent D and A material by the physical separation by the material X acting as spacer, thus allowing the two charges to separate more easily and preventing, or at least reducing, geminate recombination of the electron and hole.

The exact nature of the low bandgap material X is to be varied according to the specific energetics of the D and A materials, but examples include dithieno-benzodithiazoles (TBT), phthalocyanines, porphyrins, ruthenium dyes etc.

### EXAMPLE 1

A methodology for part of the formation of a tri-block copolymer 1 is shown in FIG. 3.

We synthesize here triblock copolymers 1 containing poly(9,9 ′-dioctylfluorene-co-benzothiadiazole (F8BT)-X- poly(9,9 ′-dioctylfluorene-co-bis-N,N ′-(4-butylphenyl)-bis-N,N ′-phenyl-1,4-phenylenediamine) (PFB) (F8BT-X-PFB) blocks forming a self-organized ternary blend structure with the required nanoscale geometry. To ensure strong phase separation, the F8BT block and PFB homopolymer may be at least partially fluorinated.

As mentioned, the standard approach of condensation polymerisation of A₂ and B₂ monomers (e.g dibromo- and diboronic esters in Suzuki couplings) leads to polydisperse polymers with no control over endgroups.

Here we use two strategies for the preparation of the reactive blocks. In the first, iterative couplings of protected halo-arylboronates are used to prepare defined oligomers of F8FBT and F8TFB with boronic acid endgroups up to the tetramer range.

For longer blocks the iterative coupling methodology may not provide practically useful amounts of materials, and hence we consider, as an alternative route, the homo-polymerisation of the unprotected halo-aryl boronate in the presence of a mono-bromo fluorine endstopper and a protected halo-arylboronate to afford a fluorene end-capped chain with protected boronate end.

Polymerization time and careful control over stoichiometries are used as a means to control the molecular weight and polydispersity.

Likewise, partially fluorinated PFB/TFB polymers with boronic ester endgroups can be prepared. Although this will likely give less precisely defined oliogmers than the iterative route due to the inherent polydispersity of condensation polymerisations, it will allow access to the higher weight blocks (in the range of n=8-20) with reactive endgroups.

With these two reactive building blocks in hand, we can synthesize the required asymmetric triblock copolymers 1, by attaching them to a variety of central non-symmetric cores via sequential Suzuki couplings (the exact coupling strategy can be tailored by slight modifications of the terminal functionalities). This will allow us to achieve block lengths up to 20 monomers and polydispersities around 1.3.

The examples described here give us the required synthetic flexibility to introduce functionality at interfaces (see FIG. 2).

Most of the semiconducting polymer used in conventional systems (for example blends of F8BT and PFB as described in the literature^{6,7}) are in the weak phase separation regime and hence the domains in ‘phase-separated’ blends will generally contain a significant fraction of the opposite polymer. Also, condensation polymerizations as used for semiconducting polymer synthesis do not easily allow for the formation of block copolymers and they do not offer control over end groups. Despite numerous efforts to synthesize well-defined block-copolymers that will form nanoscale phaseseparated structures⁸, the synthetic methodology has simply not developed to allow such structures to be made.

In the present invention, we are not restricted to requiring ‘perfect’ block copolymers to control nanoscale morphology.

Instead, the present invention includes (a) influencing phase separation of semiconducting polymer blends by altering the interaction parameter between the homopolymers and (b) synthesising ‘blocky’ copolymers that can act as surfactants and thereby control the positioning of active components in ternary blends with nm precision. This is facilitated by the most recent developments in (pseudo) controlled polymerizations of, for example, polythiophenes and develops a new generic strategy for the formation of reasonably well-defined block copolymers based on polyfluorene or polythiophene derivatives.

The use of relatively short triblock oligomers or copolymers to control the phase structure of a system comprising this triblock and, as majority components, the homopolymers that act as donor and acceptor materials, is a further embodiment of our invention. It is expected, on thermodynamic grounds, that such triblocks will interpose themselves between the homopolymers, acting as ‘surfactants’ or ‘phase directors’. Here, they simultaneously allow the desired multiple junction structure to be introduced into the structure to control the electronic properties. It is additionally desirable that the majority of the components present in the diodes are homopolymers that will generally be cheaper to synthesise than the more complex triblock structures.

We note that the use of these triblock architectures allows control of the phase-separated morphologies that are needed for solar cells, where the length scale for phase separation is required to match the diffusion range for excitons so that all photogenerated excitons will reach regions of heterojunction. The full compositional control of the well-known diblock structures, such as lamellar, columnar, gyroid, is also available with the triblock approach, and it is additionally desirable to be able to fix the characteristic length scale by the relative composition ratios of the two homopolymers and the triblock structure.

### EXAMPLE 2

Referring to FIG. 4, we demonstrate the morphological control of blend films by the inclusion of a tri-block conjugated oligomer 3′.

In this Example, both the prior art film (designated PA), provided as a 50:50 blend of F8BT and PFB, and the film of the invention 10 incorporating 5% of the tri-block oligomer 3′ with a F8BT-PFB blend as shown are spin coated from xylene solution and annealed for 30 min at 120° C.

As is readily demonstrated, the addition of the ‘triblock’ influences the phase separation, causing smaller length scale features to be formed and showing that polymer-polymer interfaces are controlled in this way.

Desirable homopolymers include those that are structurally similar to polymers frequently used in existing devices (often based on polyfluorenes and polythiophenes) but introduce relatively small modifications to alter the chi-parameter of the homopolymers and force phase separation. Polymers containing fluoro-substituents are particularly suited. The introduction of fluoro-substituents on the 9,9-dialkylfluorene building blocks is relatively straightforward, following reported earlier procedures for the introduction of modified octyl groups or by analogy with the preparation of partially fluorinated thiophene polymers. Using a similar approach we can introduce ether functionalities, other halides, or charged moieties, to force phase separation.

We have identified F8TBT as a promising polymer that can act both as an electron acceptor layer in conjunction with P3HT or as an electron donor with C60 derivatives. A preferred structure to achieve efficient charge generation uses a ternary blend, where excitons generated upon the absorption of light would dissociate near an interfacial F8TBT layer, allowing the electron to cascade down to the C₆₀ derivatives and the holes in the opposite direction in the P3HT. Without wishing to be limited by any theory, we postulate that this system would not by itself allow increasing the open circuit voltage over P3HT/PCBM, but would enable the replacement of P3HT with higher ionisation potential polythiophene polymers without loss of quantum efficiency⁴.

### EXAMPLE 3

As a first step, we synthesize a P3HT-F8TBT diblock copolymer for use in photovoltaic devices. FIG. 5 outlines the synthetic route to P3HT-F8TBT diblock copolymers that can self-organize into the desired architectures of PCBM crystals surrounded by well-ordered P3HT and a very thin F8TBT interlayer.

The P3HT with well-defined Br-endgroup can be synthesized following McCullough's (pseudo-living) GRIM polymerization. These Br-endgroups will then be used to couple onto a preformed F8TBT oligomer containing a boronic ester end group.

The preparation of the end-functionalised F8TBT makes use of recent developments in boron masking groups⁹, allowing the protection of the boronic ester functionality during cross-coupling reactions, followed by a simple and high yielding unmasking post-reaction. This allows for the defined reaction of haloaryl boronates which would otherwise polymerise through self-coupling. For example, key intermediate 3 can be readily endcapped, followed by unmasking of the boronic acid and reaction with another equivalent of 3 to build a defined dimer. Further iterations of the sequence afford longer oligomers, which can be finally coupled with P3HT after unmasking of the protected boronate to afford defined diblocks of varying size (P3HT˜10-20 monomers, F8TBT˜3-4 mer).

The examples described here give us the required synthetic flexibility to introduce functionality at interfaces.

There are several principal areas of interest which comprise a least a part of this invention: (a) the introduction of a central core with energy levels between the two homopolymers in PV devices, b) central cores with heavy atoms (iodide, Pt-copolymer, Ir complexes) will influence intersystem crossing process and influence singlet triplet processes in LEDs, (c) charged groups to screen internal fields, and (d) simple dielectric spacers to influence Coulombic interactions between charges across the interface.

Whilst the embodiments described above are provided in the context of improved photovoltaic or solar cells, the inventive concepts can also be used to advantage in organic semiconductor light-emitting diodes. All aspects of the invention in respect to the control of structure and morphology that have been described with reference to solar cells can also be used to support improved LED device architectures, noting that selection of bandgaps and positioning of HOMO and LUMO levels is adjusted to support electron-hole capture and exciton formation and emission from the material X migration of this exciton to either polymer A or D. The current paradigm for the device architecture for organic semiconductor LEDs is to use separate semiconductors to transport electrons from the cathode and holes from the anode, and to arrange electron-hole capture at the heterojunction.

The inventors have shown quite generally for polymer structures, formed either as de-mixed blends of the electron- and hole-transporting polymers² or as two-layer structures¹⁰, that electron-hole capture takes place at the heterojunction, forming first a spin-singlet charge-transfer (CT) exciton. The general problem is that for desirable choices of ionisation potential for the hole transport layer and electron affinity for the electron transport layer this CT exciton is lower in energy than the bulk exciton so that efficient emission is not generally observed.

For the model system F8BT:TFB, relatively high efficiencies (above 20 Im/W) are obtained, but result from thermal excitation of the CT exciton to the bulk (F8BT) layer where emission can take place quickly and therefore efficiently. At room temperature, the net decay time is of order 5-10 ns, a factor of ten or so longer than typical exciton decay times, allowing for competing non-radiative decay processes and limiting LED efficiency (the PL efficiency of F8BT/TFB blends is typically no more than 50%).

LEDs made by vacuum sublimation of ‘small molecules’, particularly those using triplet emitters such as the family of iridium complexes, can produce significantly higher quantum efficiencies, in part because the triplet emission makes efficient use of both singlet and triplet excitons formed by recombination, and partly because these emitters are generally included as dilute ‘guests’ within a ‘host’ semiconductor, and it is considered that these provide sites on which electron-hole capture occurs, thus avoiding the problem of CT exciton state formation, though at the penalty of increased drive voltage.

In accordance with the invention we propose a new approach to the polymer LED architecture. Our designs for the heterointerface between electron and hole transporting materials avoid the problem of the formation of strongly bound and stabilised CT excitons, and can additionally and separately provide new routes to control the branching between singlet and triplet excitons.

### EXAMPLE 4

In this embodiment we provide a means for the destabilisation of CT excitons in multiple layer LEDs. Our recent work shows that the CT exciton is strongly stabilised by the Coulomb binding energy for the electron and hole directly across the heterojunction (of order 0.5 eV at 0.5 nm separation), and is therefore lower in energy than the (desired) emissive exciton in the bulk semiconductor. Therefore, as shown in FIG. 6, we use control of the heterointerfacial structure to prevent the electron and hole from being able to come so close together, using a short section of high energy gap (or insulating) organic semiconductor 13 as the centre block of the tri-block structures shown in FIG. 2.

This centre block 13 is selected to be sufficiently thin to allow tunnelling of the electron across it to form the bulk exciton, and generally-established principles set this at a maximum of around 2 nm, if this tunnelling rate is to be appropriately rapid (ns or faster). This range of spacing greatly reduces the Coulomb binding energy, and hence de-stabilises the CT exciton against the bulk exciton, so that this CT state rapidly evolves to an emissive bulk exciton, as required for efficient LED operation.

Alternatively, if the material X is a semiconductor with a band-gap lower than that of polymers A and D, and is selected so that an exciton present on it is stable against charge separation (requiring that the offsets in HOMO position with respect to the HOMO of polymer D and/or the offsets in the LUMO position with respect to the LUMO of polymer A), then efficient radiative emission is also obtained, giving efficient LED operation.

### EXAMPLE 5

In a further embodiment we provide a means for electron spin management in multiple heterojunction LEDs. There has been a long-running controversy as to whether electron-hole capture in LEDs is spin-independent (3:1 triplet:singlet ratio) or whether spin-dependent processes can alter this ratio. For small-molecule LEDs the evidence seemed to point very clearly to the former, but there has been significant evidence that singlet fractions can be significantly higher in polymer LEDs, see for example¹¹. There is no shortage of quantum chemical models that would give rise to significant spin-dependent processes: generally, triplet exciton formation is likely to take place in the inverted Marcus regime and therefore be considerably slower that singlet formation, but the trail had in recent years gone cold.

We understand that the long-lived singlet CT exciton (formed as such by direct photoexcitation in these experiments) can decay to form a triplet exciton over a time scale of 40 ns, and provides a measure of the CT exciton intersystem crossing rate, k_{CT-ISC}. This is not very slow because the CT exchange energy is small (expected to be a few meV), though slower than the transfer rate from CT triplet to exciton triplet, k_{CT-triplet}. The design principle for spin management is to arrange that k_{CT-ISC} and k_{CT-singlet} are faster than k_{CT-triplet}. If this is the case, most CT states will evolve into singlet excitons, as has been demonstrated by Segal et al [“Extrafluorescent electroluminescence in organic light-emitting devices”, M. Segal, M. Singh, K. Rivoire, S. Difley, T. Van Voorhis, and M. A. Baldo, Nature Materials 6, 374-378 (2007).]. It has been shown that this can be in part achieved by increasing through the presence of a heavy element to enhance K_{CT-ISC}. In the present invention we modify our thin barrier layer structure, as in FIG. 6 (noting that the disposition of energy levels is not limited to that shown in this figure), to introduce more spin-orbit coupling. Straightforward ways to achieve this include the use of bromide and iodide attachments to the ‘insulating’ layer, and, at the expense of more complex synthesis, organometallic complexes can be used.

Turning now to FIGS. 7A and 7B, there is shown a schematic energy diagram of a heterojunction and a schematic representation of a blend incorporating a di-block co-polymer as an intervening, e.g. interfacial species 103 in a donor D, acceptor A homopolymer system 100.

The includsion of diblock co-polymers 103 change the morphology of homopolymer blends and alter the electronic nature of the donor-acceptor (D-A) interface.

The diblocks 103 act as surfactants that influence the interfacial energy between two homopolymers. The driving force is the incorporation of a long, semiconductor block into a semiconductor homopolymer and the exclusion of the chain end of this polymer (the second block) from said phase.

The diblock copolymers 103 include D-X (where X may be similar to the X mentioned in the patent) or D-A*, where A* is a different acceptor polymer than A and where the block length of both can be comparable in length, but more likely, the block length of D is much larger than A* (for example, A* could be a monomer or dimer).

In contrast to the triblock copolymers described above, which sit at the interface between two homopolymers by anchoring into both phases, the diblock copolymers insert one block into either the donor D or acceptor A polymer, thereby positioning the second block (or small molecule X) at the interface between the two homopolymers.

The diblock copolymers 103 specifically alter the interfacial properties of the homopolymer with which they share the largest block. After this, they introduce a new functionality on the surface of that phase, which then provides a new interface with the other homopolymer.

As will be appreciated, the invention has utility across the range of optoelectronic devices, including photovoltaics, solar cells, light emitting diodes and so on.

### REFERENCES

¹ J. J. M. Halls et al, Physical Review B 60, 5721-5727 (1999)

² A. C. Morteani, et al, Advanced Materials 15, 1708-+ (2003)

³ Y. S. Huang, et al, Nature Materials 7, 483-489 (2008)

⁴ H. Ohkita, et al, Journal of the American Chemical Society 130, 3030-3042 (2008)

⁵ R. A. Marsh, et al, Nano Letters 8, 1393-1398 (2008)

⁶ A. C. Morteani, et al, Journal of Chemical Physics 122, 244906 (2005)

⁷ A. C. Morteani, et al, Physical Review Letters 92, 247402/1-4 (2004)

⁸ U. Scherf, et al, Accounts of Chemical Research 41, 1086-1097 (2008)

⁹ H. Noguchi, et al, Journal of the American Chemical Society 129, 758-759 (2007)

¹⁰ A. C. Morteani, et al, Applied Physics Letters 86 (2005)

¹¹ J. S. Wilson, et al, Nature 413, 828-831 (2001)

1. A photovoltaic device having an electron donor D semiconducting species, an electron acceptor A semiconducting species and an intervening co-oligomeric or co-polymeric species provided to alter energy transfer characteristics of excitons to or from an interface between the electron acceptor A semiconducting species and the electron donor D semiconducting species, wherein the intervening co-oligomeric or co-polymeric species is or comprises a material with a bandgap lower than that of the electon acceptor A semiconducting species and the electron donor D semiconducting species to either side.

2. (canceled)

3. A device according to claim 1, wherein the intervening species is a co-oligomer.

4. A device according to claim 1, wherein the intervening species is Am-Xn-Do, where m, n and o are each 0 or a positive integer and at least two of A, X and D are present.

5. A device according to claim 1, wherein the acceptor and donor species are at least partially halogenated.

6-8. (canceled)

9. A device according to claim 1, wherein the intervening species is less than 2 nm thick.

10. (canceled)

11. A photovoltaic device having a layer comprising a conjugated polymeric donor material D, a conjugated polymeric acceptor material A and a further species Aₘ-Xₙ-Dₒ, where m, n and o are each 0 or a positive integers and at least two of A, X and D are present in the further species.

12. A device according to claim 11, wherein the further species is selected from A-D, X-D or A-X.

13. A device according to claim 12, wherein the further species is A-D and a block length of D is larger than a block length of A, or vice versa.

14. A device according to claim 12, wherein the further species is X-D and X is a small molecule and D is a polymer.

15. A method of forming a photovoltaic device comprising blending a donor material D, an acceptor material A and a species Aₘ-Xₙ-Dₒ, where m, n and o are each 0 or a positive integer and wherein at least two of A, X and D are present, and X has a lower band gap than either A or D.

16. A method in accordance with claim 15, comprising controlling a length scale for phase separation between materials A and D by selecting relative quantities of A, D and the species Am-Xn-Do.

17-18. (canceled)

19. A material of the form Aₘ-Xₙ-Dₒ, where m, n and o are each a positive integer and X has a lower band gap than either A or D wherein the material is adapted for use as an interfacial species in an optoelectronic device.

20. A device according to claim 11, wherein X is selected from the group consisting of dithieno-benzodithiazoles (TBT), phthalocyanines, porphyrins, and ruthenium dyes.

21. (canceled)

22. A device according to claim 1, wherein the intervening species is a di-block oligomer or a tri-block co-polymer.

23. A device according to claim 11, wherein each of A, X and D are present in the further species and X has a lower band gap than either A or D.

24. A method according to claim 15, wherein X is selected from the group consisting of dithieno-benzodithiazoles (TBT), phthalocyanines, porphyrins, and ruthenium dyes.

25. A material according to claim 19, wherein X is selected from the group consisting of dithieno-benzodithiazoles (TBT), phthalocyanines, porphyrins, and ruthenium dyes.
